(19) United States
(12) Patent Application Publication
(10) Pub. No.: US 2020/0185158 A1
(43) Pub. Date: Jun. 11, 2020

(54) Broadband and Tunable Organic-Inorganic Hybrid Short-Wave Infrared Materials

(71) Applicant: Temple University-Of The Commonwealth System of Higher Education, Philadelphia, PA (US)

(72) Inventors: Yi Rao, North Logan, UT (US); Bradford B. Wayland, Philadelphia, PA (US); Hai-Lung Dai, Broomall, PA (US); Xia Li, North Logan, UT (US)

(21) Appl. No.: 16/345,829

(22) PCT Filed: Oct. 31, 2017
(86) PCT No.: PCT/US17/59151

§ 371 Date: Apr. 29, 2019

Related U.S. Application Data
(60) Provisional application No. 62/417,024, filed on Nov. 3, 2016.

(51) Int. Cl. H01G 9/20; H01L 51/00; H01G 9/00; H01L 51/42; C03C 17/00

(52) U.S. Cl. CPC H01G 9/2009; H01L 51/0007; H01G 9/0036; H01L 51/4253; H01L 51/0028; C03C 2217/212; H01L 51/0077; H01G 9/2018; C03C 2218/116; C03C 2217/28; C03C 17/009

(57) ABSTRACT

The present invention relates in part to short-wave IR (SWIR) materials comprising generic mixed salts of empirical formula AₐB_{b}M_{c}X_{d} that are composition-dependent, broadband, and tunable. These materials have unique light absorbance wavelengths from 0.4 to 2.6 μm, including both the visible and SWIR. The preparation procedure for the SWIR materials is simple, including the use of widely available, cheap, and non-toxic precursors, unlike existing state of the art alloy SWIR materials. These novel materials have broad applications in security, surveillance, military, machine vision, photovoltaic solar cells, medical treatments, spectroscopy detector, and thermography. The present invention also relates to methods of fabricating a film comprising the composition of the invention and to photovoltaic stacks comprising the composition of the invention.

### CROSS-REFERENCE TO RELATED APPLICATIONS

This application claims priority from U.S. Provisional Patent Application Ser. No. 62/417,024, filed Nov. 3, 2016, the entire content of which is incorporated herein by reference.

### BACKGROUND OF THE INVENTION

The short-wave infrared (SWIR) materials are an important focus of defense, security, and scientific research and development. The demand for the short-wave IR materials has increased for scientific, defense applications, and sustainable energy sources. For security and defense applications, short-wave infrared (SWIR) detectors find a number of advantages compared to visible when used in a variety of applications including electronic board inspection, produce inspection, identifying and sorting, surveillance, anti-counterfeiting, process quality control, and much more. However, traditional inorganic short-wave IR materials are expensive, environmentally toxic with small-area and under highly-demanding detection conditions. In the photovoltaic applications, existing materials suffer from a narrow UV-visible absorption of solar radiation and leave near-IR to short-wave IR unexploited. Therefore, there is a need in the art for novel short-wave IR materials with improved optoelectronic and photovoltaic properties. Other applications and related industries, such as security, surveillance, military, machine vision, medical devices and treatments, spectroscopy detectors, and thermography, can likewise benefit from the development of novel short-wave IR materials. The present invention addresses these continuing needs in the art.

### SUMMARY OF INVENTION

In one aspect, the invention relates to a composition comprising a mixed salt of empirical formula AₐB_{b}M_{c}X_{d}, wherein A is an organic cation; B is a cation which is different from A; M is a metallic cation; X is a halogen anion; and a, b, c, and d are numbers expressing the relative molar proportions of the cations and anions. In one embodiment, B is an inorganic cation. In one embodiment, the composition is crystalline. In one embodiment, the van der Waals radii of cation A and cation B are in the range of 200-280 pm. In one embodiment, A is methylammonium or formamidinium. In another embodiment, B is hydrazinium, hydroxylammonium, methylammonium, or formamidinium. In one embodiment, M is Pb, Sn, or Ge. In another embodiment, X is iodide, bromide, or chloride. In one embodiment, the empirical formula of the mixed salt can be represented by the formula (CH₃NH₃)ₓ(NH₂NH₃)₁₋ₓPbI₃, wherein 0≤x≤1. In one embodiment, x is 0.875, 0.5, 0.4, 0.25, or 0.2.

In another aspect, the invention relates to a thin film comprising a composition comprising the composition of the invention. In one embodiment, the film has a thickness between 300 and 500 nm.

In one aspect, the invention relates to a method of fabricating a film of a composition comprising a mixed salt of empirical formula AₐB_{b}M_{c}X_{d}; wherein A is an organic cation; B is an inorganic cation or an organic cation which is different from A; M is a metallic cation; X is a halogen anion; and a, b, c, and d are numbers expressing the relative molar proportions of the cations and anions; the method comprising: providing a mixture comprising a first organic halide AX, an inorganic halide or second organic halide BX, a metallic halide MX₂, and a solvent; heating a substrate at a temperature T_{sub}; and disposing the mixture on the substrate. In one embodiment, the step of disposing the mixture on the substrate comprises hot-casting the mixture on the substrate. In another embodiment, the step of disposing the mixture on the substrate comprises spin-coating the substrate on the substrate. In one embodiment, T_{sub} is between 50° C. and 130° C.

In another aspect, the invention relates to a photovoltaic stack comprising a substrate, an electron transport layer, a hole transport layer, and a layer comprising a mixed salt of empirical formula AₐB_{b}M_{c}X_{d}; wherein A is an organic cation; B is an inorganic cation or an organic cation which is different from A; M is a metallic cation; X is a halogen anion; and a, b, c, and d are numbers expressing the relative molar proportions of the cations and anions. In one embodiment, the electron transport layer comprises TiO₂. In one embodiment, the hole transport layer comprises Spiro-MeOTAD.

In another aspect, the invention relates to a photodetector device comprising a photovoltaic stack comprising a substrate, an electron transport layer, a hole transport layer, and a layer comprising a composition of the present invention.

In another aspect, the invention relates to a solar cell comprising a photovoltaic stack comprising a substrate, an electron transport layer, a hole transport layer, and a layer comprising a composition of the present invention.

### BRIEF DESCRIPTION OF THE DRAWINGS

The following detailed description of various embodiments of the invention will be better understood when read in conjunction with the appended drawings. For the purpose of illustrating the invention, there are shown in the drawings various embodiments. It should be understood, however, that the invention is not limited to the precise arrangements and instrumentalities of the embodiments shown in the drawings.

FIG. 1 is a chart depicting the vis-IR absorbance spectra of mixed (CH₃NH₃)ₓ(NH₂NH₃)₁₋ₓPbI₃, here MA=CH₃NH₃, thin films for five molar fractions of x_{MA}=87.5%, 50%, 40%, 25% and 20% (percentages based on the initial concentrations of the precursors; actual composition of the crystallized films may differ).

FIG. 2(A) is a chart depicting the vis-IR absorbance spectra of a mixed thin film of x_{MA}=87.5% made at different temperatures on hot-casted glass substrates. FIG. 2(B) is a chart depicting the X-ray diffraction (XRD) pattern of the films. FIG. 2(C) is a series of photographs including the optical images for the thin films at RT, 80° C., 100° C., and 120° C.; MAI=CH₃NH₃I.

FIG. 3(A) is a chart depicting the vis-IR absorbance spectra of glass films by hot-casting at different temperature for composition of x_{MAI}=100% (pure MAPbI₃). FIG. 3(B) is a chart depicting the X-ray diffraction pattern of the glass films hot-casted at different temperatures for composition of x_{MAI}=100% (pure MAPbI₃; MA=CH₃NH₃).

FIGS. 4(A), and 4(B), include a series of photographs of two glass films of (MA)ₓ(NH₂NH₃)₁₋ₓPbI₃ where x_{MAI}=100% and 50% after storage for 2 weeks in a desiccator with gentle vacuum, as compared with those of as-prepared thin films (FIG. 4(A)), and photographs of the two glass films of (MA)ₓ(NH₂NH₃)₁₋ₓPbI₃ (x_{MAI}=100%, 50%) with exposure to the ambient condition under dark at the time of as-prepared (0 day), after 18 days, and after 55 days (FIG. 4(B)); MA=CH₃NH₃ and MAI=CH₃NH₃I.

FIG. 5 is a chart with an inset photograph, depicting the UV-vis spectra of the three precursor solutions, including PbI₂ alone in γ-butyrolactone (GBL), a mixture of PbI₂ and MAI (CH₃NH₃I) in GBL, and a mixture of PbI₂, MAI, and NH₂NH₃I in GBL; pictured in the inset are the solutions prepared from the three precursors. The presence of NH₂NH₃I significantly increases the solubility of PbI₂.

FIGS. 6(A), and 6(B), include a series of scan electron microscope (SEM) images of the short-wave IR film with x_{MAI}=20%. The films show highly uniform and pinhole free coverage at a scale of 100 μm (FIG. 6(A)), and at a scale of 5 μm (FIG. 6(B)); MAI=CH₃NH₃I.

FIG. 7 is a chart depicting the photoluminescence spectra for the short-wave IR films with a molar fraction of x_{MAI}=25%, 50%, and 100%. A continuous-wave (cw) He—Ne laser was used in the photoluminescence measurements; MAI=CH₃NH₃I.

FIG. 8 is a chart depicting the photoluminescence kinetic traces of the short-wave IR films for x_{MAI}=25%, 50% and 100% under low fluence of ˜10¹⁴ photons/cm³. The lifetimes are 36.9 ns, 17.7 ns, and 6.7 ns for x_{MAI}=25%, 50% and 100%, respectively. MAI=CH₃NH₃I.

FIGS. 9(A), and 9(B), depict the schematics of the configuration and architecture of a planar solar cell device (FIG. 9(A)), and the photograph of the solar cells made with the short-wave IR materials of the invention (FIG. 9(B)).

FIG. 10 is a scan electron microscope (SEM) image of a film obtained by one step hot-casting at substrate temperature of 100° C., and precursor solution temperature of 70° C. The architecture of the device is FTO/TiO₂/perovskite/HTM.

FIG. 11 is a schematic depicting the setup for current measurements for short-wave IR devices. A SLS201 light source (Thorlabs, USA) generated white light, which is focused on the entrance slit of a CM110 Monochromator (Spectral Products, USA). A SR540 chopper (Stanford Research System, USA) is placed right after monochromator to create square light. After a lens pair, the beam focused on the solar cell with the spot size of 4 mm². A 2401 source meter (Keithley, USA) was used to sweep voltage from −1.0 V to 1.0 V with a step of 0.02 V and currents were taken at the same time.

FIG. 12 is a chart depicting the current density generated by a short-wave IR device of x_{MAI}=87.5% from 1000 nm to 1700 nm with a step length of 50 nm by rotating a grating in the monochromator, under the four applied voltages, −0.9 V, −0.8 V, −0.7 V, and 0 V. “−” represents that the negative terminal from the source meter is connected with the FTO contact and the positive terminal from the source meter is connected with the gold contact. Under zero and positive biased, no current was generated in this wavelength range. On the other hand, under negative biased, the current was generated and changes as a function of wavelength. The current density is peaked at 1100 nm. With increasing the negative biased, the current increases accordingly.

FIGS. 13(A), and 13(B), include a series of charts depicting the current-voltage curve for the conversion efficiency of a mixed (MA)ₓ(NH₂NH₃)₁₋ₓPbI₃—based solar cell (x_{MAI}=87.5%; FIG. 13(A)), and the incident-photon-converted electron efficiency from 300 nm to 900 nm (FIG. 13(B)). All the preparation procedures were performed under ambient condition.

### DETAILED DESCRIPTION

The invention discloses short-wave IR (SWIR) materials that are composition-dependent, broadband, and tunable, such as for example the organic-inorganic-metallic cation hybrid material (CH₃NH₃)ₓ(NH₂NH₃)₁₋ₓPbI₃. These materials have unique light absorbance wavelengths from 0.4 to 2.6 μm, and are the basis of various photodetector and photovoltaic based devices and applications, such as short-wave IR detectors and photovoltaic solar cells. The invention includes methods of making and using these materials.

### Definitions

It is to be understood that the figures and descriptions of the present invention have been simplified to illustrate elements that are relevant for a clear understanding of the present invention, while eliminating, for the purpose of clarity, many other elements found in the art related to perovskite chemistry, solar cell and other photovoltaic devices, and the like. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this invention belongs. Although any methods, materials and components similar or equivalent to those described herein can be used in the practice or testing of the present invention, various embodying methods and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, ±10%, ±5%, ±1%, or ±0.1% from the specified value, as such variations are appropriate.

Throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, 6 and any whole and partial increments therebetween. This applies regardless of the breadth of the range.

### Compositions and Materials of the Invention

In one aspect, the invention relates to a composition comprising a mixed salt of empirical formula AₐB_{b}M_{c}X_{d}, wherein A is an organic cation, B is a cation which is different from A, M is a metallic cation, X is a halogen anion, and a, b, c, and d are numbers expressing the relative molar proportions of the cations and anions.

In some embodiments, the organic cation A comprises carbon and a protonated nitrogen. In one embodiment, the organic cation A carries a +1 charge. Non-limiting examples of organic cations include methylammonium, dimethylammonium, trimethylammonium, ethylammonium, aziridinium, diaziridinium, formamidinium, amidinium, and guanidinium. In one embodiment, the organic cation is methylammonium. In one embodiment, the organic cation is formamidinium.

In some embodiments, the composition comprises an inorganic cation B. In some embodiments, the inorganic cation B comprises a protonated nitrogen atom. In one embodiment, B comprises a protic cation. In one embodiment, B comprises a nitrogen atom with a formal charge of +1. In one embodiment, the inorganic cation B may be made by protonating an amine-containing compound such as with an acid. Exemplary inorganic cations include, but are not limited to, ammonium, hydroxylammonium, and hydrazinium. In one embodiment, the inorganic cation B is hydroxylammonium. In another embodiment, the inorganic cation B is hydrazinium.

In some embodiments, the composition comprises an organic cation A and an inorganic cation B. In other embodiments, the composition comprises a first organic cation A and a second organic cation B, wherein the organic cations represented by A and B are different. In one embodiment, both A and B represent organic cations. In one embodiment, A represents an organic cation selected from the group consisting of methylammonium or formamidinium. In one embodiment, B represents formamidinium and A does not represent formamidinium. In one embodiment, B represents methylammonium and A does not represent methylammonium.

Non-limiting examples of metallic cations are lead (Pb), tin (Sn), or germanium (Ge). In one embodiment, the metallic cation is Pb²⁺. Non-limiting examples of halogen atoms include fluorine, chlorine, bromine, and iodine; their respective anions may be fluoride, chloride, bromide, and iodide. In one embodiment, the halogen is iodide.

In some embodiments, the compositions of the invention are mixed organic-inorganic-metallic salts. The formula of the salts depends largely on the method of making the salts, i.e., on the initial ratio between the various precursors of the mixed salt. For example, the generic mixed salt AₐB_{b}M_{c}X_{d} can be generated by mixing precursor halides AX, BX, and MX in various ratios. In embodiment, the halide is iodine, A and B are monocations of formula AI and BI, respectively, and M is a dication of formula MI₂. In such an embodiment, the mixed salt may be prepared by mixing AI, BI, and MI₂. If, in a non-limiting example, the ratio between the salts is 0.5:0.5:1, the resulting salt is of the formula A_{0.5}B_{0.5}MI₃. As would be readily apparent to one of skill in the art, variations between rations of the starting precursors and the formula of the resulting salt are possible, and expected in most cases. For example, even if the ratio of the precursors differs from 0.5:0.5:1, the formula of the resulting mixed salt can still be A_{0.5}B_{0.5}MI₃. One of ordinary skill in the art would recognize that the formulas A_{0.5}B_{0.5}MI₃ and A₁B₁M₂I₆ represent the same material. The ratios referred to herein are generally understood to be, but not necessarily limited to, molar ratios.

In one embodiment, A is CH₃NH₃⁺, B is NH₂NH₃⁺, M is Pb²⁺, and X is I⁻. In one embodiment, the ration of A:B:M is 1:1:2 and the resulting mixed salt may be represented by the formula (CH₃NH₃)(NH₂NH₃)Pb₂I₆. In one embodiment, the ratio of a, b, c, and d in the generic formula AₐB_{b}M_{c}X_{d} can be represented as (a+b+2c=d), such as would be understood by one of skill in the art. Exemplary compositions of the invention include, but are not limited to, (CH₃NH₃)₇(NH₂NH₃)Pb₄I₁₆, (CH₃NH₃)(NH₂NH₃)PbI₄, (CH₃NH₃)₄(NH₂NH₃)₆Pb₅I₂₀, (CH₃NH₃)(NH₂NH₃)₃Pb₂I₈, (CH₃NH₃)₂(NH₂NH₃)₈Pb₅I₂₀, CH₃NH₃)₇(NH₃OH)Pb₄I₁₆, (CH₃NH₃)(NH₃OH)PbI₄, (CH₃NH₃)₄(NH₃OH)₆Pb₅I₂₀, (CH₃NH₃)(NH₃OH)₃Pb₂I₈, (CH₃NH₃)₂(NH₃OH)₈Pb₅I₂₀, CH₃NH₃)₇(NH₂═CHNH₂)Pb₄I₁₆, (CH₃NH₃)(NH₂═CHNH₂)PbI₄, (CH₃NH₃)₄(NH₂═CHNH₂)₆Pb₅I₂₀, (CH₃NH₃)(NH₂═CHNH₂)₃Pb₂I₈, (CH₃NH₃)₂(NH₂═CHNH₂)₈Pb₅I₂₀, (NH₂═CHNH₂)₇(NH₂NH₃)Pb₄I₁₆, (NH₂═CHNH₂)(NH₂NH₃)PbI₄, (NH₂═CHNH₂)₄(NH₂NH₃)₆Pb₅I₂₀, (NH₂═CHNH₂)(NH₂NH₃)₃Pb₂I₈, (NH₂═CHNH₂)₂(NH₂NH₃)₈Pb₅I₂₀, (NH₂═CHNH₂)₇(NH₃OH)Pb₄I₁₆, (NH₂═CHNH₂)(NH₃OH)PbI₄, (NH₂═CHNH₂)₄(NH₃OH)₆Pb₅I₂₀, (NH₂═CHNH₂)(NH₃OH)₃Pb₂I₈, (NH₂═CHNH₂)₂(NH₃OH)₈Pb₅I₂₀, (NH₂═CHNH₂)₇(CH₃NH₃)Pb₄I₁₆, (NH₂═CHNH₂)(CH₃NH₃)PbI₄, (NH₂═CHNH₂)₄(CH₃NH₃)₆Pb₅I₂₀, (NH₂═CHNH₂)(CH₃NH₃)₃Pb₂I₈, and (NH₂═CHNH₂)₂(CH₃NH₃)₈Pb₅I₂₀.

In one embodiment, the ratio of (A+B):M is 1:1. In one embodiment, the number c in the generic mixed salt AₐB_{b}M_{c}X_{d} is 1, and the relationship between a and b can be defined as (a+b=1). Non-limiting examples of compositions for which the ratios of A, B, and M in the generic formula AₐB_{b}M_{c}X_{d} can be represented as [(A+B):M=1:1] are included in Table 1. In the non-limiting examples shown in Table 1, A represents CH₃NH₃⁺, B represents NH₂NH₃⁺, M represents Pb, and X represents I.

TABLE 1
Mixed Salts of Formula (CH₃NH₃)ₐ(NH₂NH₃)_{b}Pb_{c}I_{d}

| CH₃NH₃⁺:NH₂NH₃⁺ | Mixed Salt Formula |
|---|---|
| 0.875:0.125 | (CH₃NH₃)_{0.875}(NH₂NH₃)_{0.125}PbI₃ |
| 1.00:1.00 | (CH₃NH₃)_{0.5}(NH₂NH₃)_{0.5}PbI₃ |
| 0.40:0.60 | (CH₃NH₃)_{0.4}(NH₂NH₃)_{0.6}PbI₃ |
| 0.25:0.75 | (CH₃NH₃)_{0.25}(NH₂NH₃)_{0.75}PbI₃ |
| 0.20:0.80 | (CH₃NH₃)_{0.2}(NH₂NH₃)_{0.8}PbI₃ |

In one embodiment, (a+b=1) and thus (b=1−a). Non-limiting examples of such compositions include: (NH₂═CHNH₂)ₐ(NH₂NH₃)₁₋ₐPbI₃, (NH₂═CHNH₂)ₐ(NH₃OH)₁₋ₐPbI₃, (CH₃NH₂)ₐ(NH₃OH)₁₋ₐPbI₃, and (CH₃NH₂)ₐ(NH₂═CHNH₂)₁₋ₐPbI₃.

In another embodiment, the composition is substantially crystalline. In one embodiment, the size of the organic and/or inorganic cations represented by A and B can be estimated using their respective van der Waals radii, as would be understood by one of skill in the art. In one embodiment, the van der Waals radii are between 100 pm and 500 pm. In one embodiment, the van der Waals radii are between 150 pm and 400 pm. In one embodiment, the van der Waals radii are between 150 pm and 300 pm. In one embodiment, the van der Waals radii of the organic and inorganic cations are between 200 and 280 pm.

As is readily apparent to one of skill in the art, the compositions and materials of the invention can be characterized by various methods, such as ultra violet (UV) and short wave infrared (SWIR) spectroscopy, X-ray diffraction (XRD), and scanning electron microscopy (SEM). These methods can be performed on thin films and/or single crystals comprising the materials and compositions of the invention.

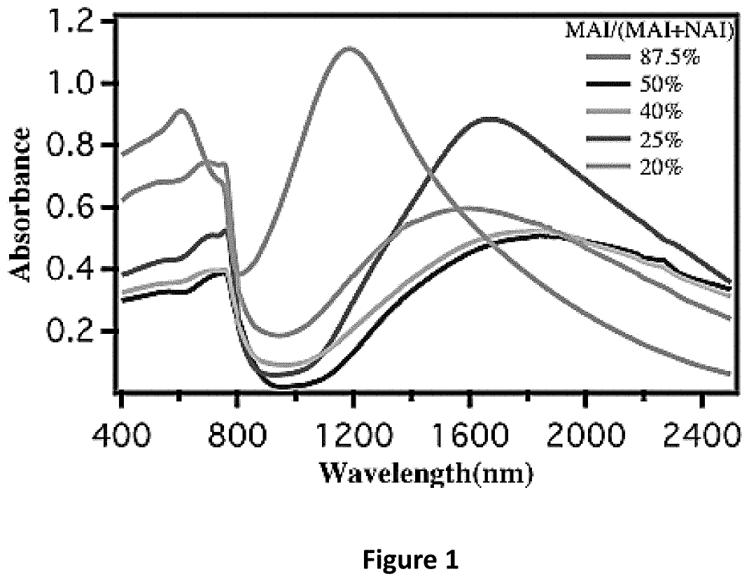

In one embodiment, as shown for example in FIG. 1, the materials and compositions of the invention may be tunable in their properties. In one embodiment, the properties of the composition of the invention may be tuned by varying the ratio between organic cation A, inorganic or organic cation B, and metallic cation M in the generic mixed salt of empirical formula AₐB_{b}M_{c}X_{d}. In some embodiments, the materials can be tuned by controlling the ratio between the precursors, for example the ratio between organic cation A and organic or inorganic cation B. In some embodiments, the ratio between the organic and inorganic cations is varied in the preparation of the thin films by using various molar fractions of precursor salt AX in the mixture of precursor salts AX and BX, such as via the relationship x_{AX}=[AX]/([AX]+[BX]), where x represents the molar fraction of precursor salt AX and brackets indicate molarity, such as would be understood by one of skill in the art. In one embodiment, the resulting mixed salts can be represented by the empirical formula AₓB₁₋ₓPb_{c}I_{d}. One of ordinary skill in the art would understand that the empirical formula AₓB₁₋ₓPb_{c}I_{d} is equivalent to the empirical formula AₐB₁₋ₐPb_{c}I_{d} discussed elsewhere herein.

In some embodiments of the invention, the addition of organic cation A and inorganic or organic cation B to a halide perovskite material MX₂ results in a mixed salt that exhibits strong and broad absorbance in the short-wave IR spectrum. In some embodiments, strong and broad absorbance occurs in the short-wave IR range of 800 nm-2500 nm when an organic cation or an inorganic cation such as NH₂NH₃⁺ is added to a perovskite material, in addition to the typically high absorbance of halide perovskite in the visible region. In one embodiment, the absorbance peaks are located at 1180 nm, 1860 nm, 1778 nm, 1681 nm, and 1600 nm for molar fractions of x_{AX}=0.875, 0.50, 0.40, 0.25 and 0.20, respectively. In one embodiment, the broadband short-wave IR peak shifts to a longer wavelength when x_{AX} is lowered from 0.875 to 0.50. In one embodiment, the broadband short-wave IR peak shifts to a shorter wavelength as the molar fraction x_{AX} decreases from 0.50 to 0.20. In one embodiment, the absorbance exhibits a maximum peak at 1860 nm at a molar fraction of x_{AX}=0.50, as shown for example in the inset of FIG. 1.

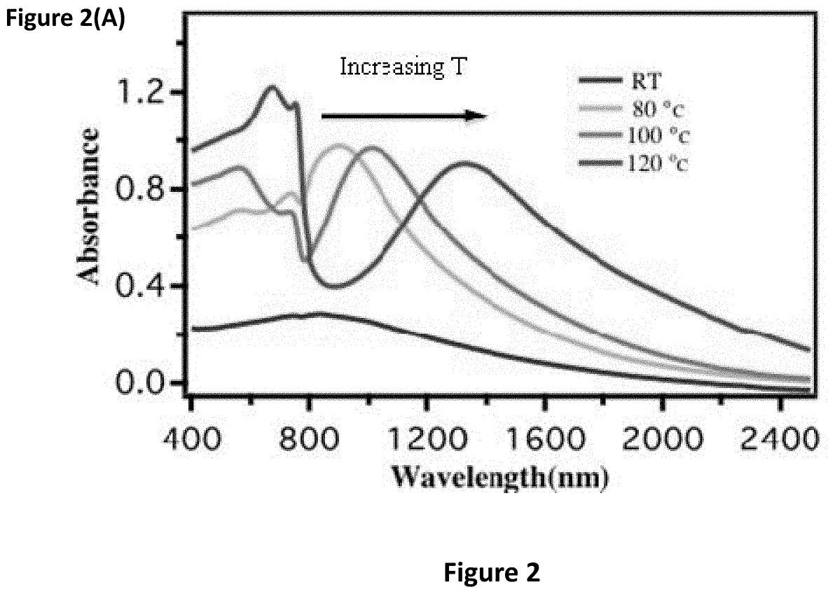

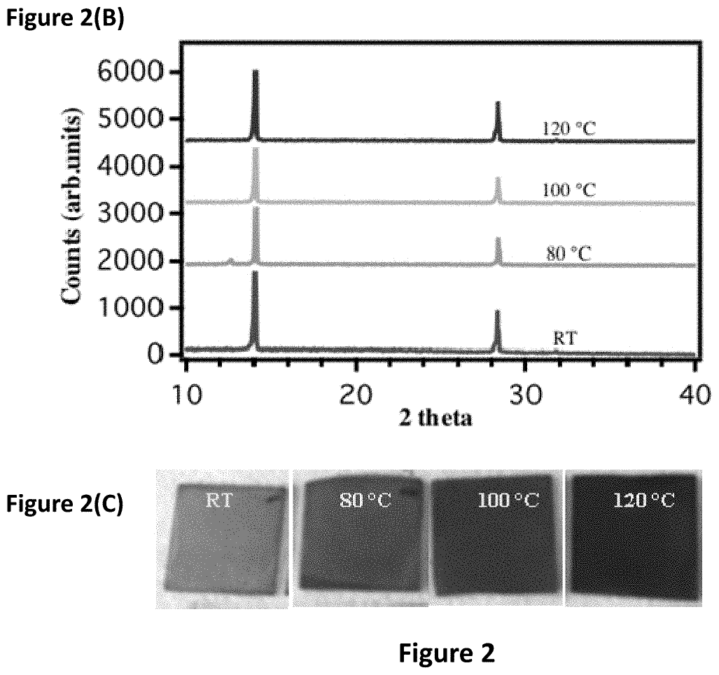

In one embodiment, the XRD peaks of the organic-inorganic-metallic mixed crystalline salt of the invention are the same as those for the corresponding pure organo-metallic perovskite, for example APbI₃ where A=CH₃NH₃⁺, suggesting that the perovskite structures are not disrupted with the addition of an inorganic halide such as NH₂NH₃I. The hydrazinium cation (NH₂NH₃⁺) has the same molecular size as the methylammonium cation (CH₃NH₃+), as evidenced in part by its van der Waals radius of 217 pm. While not wishing to be bound by any particular scientific theory, it is possible that the cation B partially substitutes cation A in the unit cell of the 3D structure of APbI₃ as the main structure still remains. In one embodiment, the cation B, such as hydrazinium (NH₂NH₃+), can fit into the space of four adjacent corner-sharing octahedral PbI₆ to produce a close-packed 3D structure. In one embodiment, X-ray diffraction (XRD) analysis can be used to analyze the results of varying T_{sub} on the interaction of the resulting materials with short-wave IR. In some embodiments, XRD analysis was performed on thin films fabricated at different temperatures of substrates (T_{sub}). As shown in FIG. 2(B), in one embodiment, the XRD pattern that the main 20 peaks of x_{AX}=0.875 thin films are located at 14.04° (110) and 28.3° (220), respectively. In one embodiment, those peaks are the same as those for pure perovskite APbI₃, where A=CH₃NH₃. In another embodiment, the perovskite structures are not disrupted with the addition of inorganic or second organic cation B.

### Methods of the Invention

In another aspect, the invention relates to a method of fabricating a film, such as a thin film, comprising the composition of the invention, on a substrate. In one embodiment, the method of fabricating the film includes the steps of providing a mixture comprising a first organic halide AX, an inorganic halide or a second organic halide BX, a metallic halide MX₂, and a solvent; heating the substrate at a temperature T_{sub}; and disposing the mixture on the substrate. Any suitable methods for mixing the precursor salts and/or solvents can be used. Any methods suitable for heating the substrate at the temperature T_{sub} can be used. In one embodiment, the step of disposing the mixture on the substrate comprises hot-casting the mixture on the substrate. In another embodiment, the step of disposing the mixture on the substrate comprises spin-coating the mixture onto the substrate. As readily apparent, any method known in the art of hot-casting, and/or spin-coating, can be used. The use of these techniques does not exclude using other similar or complementary techniques.

In one embodiment, T_{sub} is between 25° C. and 300° C. T_{sub} is between 25° C. and 200° C. In one embodiment, T_{sub} is between 50° C. and 130° C. In one embodiment, the temperature T_{sub} used in the fabrication of the film can affect the resulting properties. In one embodiment, the temperature at which certain steps occur in the fabrication of the film can affect its interaction with broadband short-wave IR. In some embodiments, Vis-IR spectra may be collected for mixed AₓB₁₋ₓPbI₃, where, for example, A=CH₃NH₃, and B=NH₂NH₃; exemplary spectra are shown in FIG. 2(A). In one embodiment, thin films with a molar fraction of x_{AX}=0.875, such as when AX=CH₃NH₃I, may be fabricated under different deposition temperatures T_{sub}. As described elsewhere herein, the fabrication method includes heating a substrate at a temperature T_{sub}. In one embodiment, a red shift occurs as T_{sub} increases from room temperature to 120° C. In one embodiment, no distinct short-wave IR peak is observed for T_{sub}=room temperature (RT). In one embodiment, the near IR peak at 907 nm appears at T_{sub}=80° C. and shifts to 1333 nm at T_{sub}=120° C.

In one embodiment, the thickness of a film comprising the composition of the invention is between 100 and 1000 nm. In one embodiment, the thickness of a film comprising the composition of the invention is between 150 and 800 nm. In one embodiment, the thickness of a film comprising the composition of the invention is between 200 and 700 nm. In one embodiment, the thickness of a film comprising the composition of the invention is between 250 and 600 nm. In one embodiment, the thickness of a film comprising the composition of the invention is between 300 and 500 nm.

In one aspect, the invention relates to a photovoltaic stack comprising a substrate, an electron transport layer, a hole transport layer, and a layer comprising the composition of the invention. In one embodiment, the electron transport layer comprises TiO₂. In one embodiment, the hole transport layer comprises Spiro-MeOTAD. These embodiments should be seen as to limit the possible materials used in the electron and hole transport layers, any materials known in the art can be used to formulate electron and hole transport layers. Any suitable material can be used for the substrate. In one embodiment, the substrate is made of an electrically conductive material, such as an electrically conductive glass. In one embodiment, the glass is a fluorine-doped tin oxide (FTO) coated glass. The photovoltaic stack can comprise any other suitable elements known ion the art. In one embodiment, the stack includes an electrode, for example a gold electrode.

In one aspect, the invention relates to a photodetector device comprising a photovoltaic stack comprising a substrate, an electron transport layer, a hole transport layer, and a layer comprising the composition of the invention. In one embodiment, the device is a solar cell comprising a photovoltaic stack as described elsewhere herein.

### EXPERIMENTAL EXAMPLES

The invention is further described in detail by reference to the following experimental examples. These examples are provided for purposes of illustration only, and are not intended to be limiting unless otherwise specified. Thus, the invention should in no way be construed as being limited to the following examples, but rather, should be construed to encompass any and all variations which become evident as a result of the teaching provided herein.

Without further description, it is believed that one of ordinary skill in the art can, using the preceding description and the following illustrative examples, make and utilize the compositions of the present invention and practice the claimed methods. The following working examples therefore, specifically point out various embodiments of the present invention, and are not to be construed as limiting in any way the remainder of the disclosure.

### Example 1: Fabrication of Short-Wave IR Materials

### Precursors Preparation

### Synthesis of CH₃NH₃I

methylammonium iodide (CH₃NH₃I, MAI) was synthesized by the reaction of hydroiodic acid (HI, 57 wt. % in water, Sigma Aldrich) with methylamine solution (CH₃NH₂, 33 wt. % in ethanol, Sigma Aldrich) at 0° C. by stirring for 2 hours. The resultant solution was evaporated at 60° C. under vacuum for one hour. The precipitate was washed with diethyl ether for three times and finally dried at 60° C. in a vacuum oven to yield a white powder.

### Synthesis of NH₂NH₃I

hydrazinium iodide (NH₂NH₃I) was synthesized by the reaction of hydroiodic acid (HI, 57 wt. % in water, Sigma Aldrich) with hydrazine (98%, Sigma Aldrich) at 0° C. The hydroiodic acid was added to the hydrazine solution diluted with ethanol (50%) slowly until a precipitate occurred. The final snow-white NH₂NH₃I powder was obtained by re-crystallization from cooled ethanol.

### Short-Wave IR Thin Film

A mixture of CH₃NH₃I and NH₂NH₃I, and PbI₂ (Sigma Aldrich) was dissolved in anhydrous N,N-dimethylformamide (DMF). The total molarity of CH₃NH₃I and NH₂NH₃I was kept twice that of PbI₂. The concentration of PbI₂ was fixed at 0.5 M (230 mg/ml), while the ratio of CH₃NH₃I to NH₂NH₃I varied for various molar fractions. x in (CH₃NH₃)ₓ(NH₂NH₃)₁₋ₓPbI₃ is defined as the mole fraction of CH₃NH₃I in the mixture of CH₃NH₃I and NH₂NH₃I: x_{MAI}=m_{MAI}/(m_{MAI}+m_{NH}_{₂}_{NH}_{₃}_{I}), m_{MAI} and m_{NH}_{₂}_{NH}_{₃}_{I} are molarity of CH₃NH₃I and NH₂NH₃I. The perovskite thin films were deposited on glass substrate through a hot-casting process. The mixture solution of the precursors in DMF was always kept at 70° C. during the whole process. For different composition films, the glass substrate was heated to 120° C. on a hot plate. During the spin coating, the hot substrate was quickly transferred to the spin coater chuck, and the precursor solution was dropped on the substrate using a pipette. The coating process was started immediately. The spin coater was programmed for acceleration to reach a speed of 3000 rpm in 2 seconds. After spinning for 15 seconds, the substrate was transferred to a vacuum oven to evaporate residual solvent at 120° C. for 10 minutes. For temperature dependent thin films, the glass substrate was heated to the temperature of interest.

### Short-Wave IR Single Crystals

Anti-solvent vapor-assisted crystallization methods were used to prepare short-wave IR single crystals. A mixed cation iodides (CH₃NH₃I and NH₂NH₃I) and PbI₂ (3:1 by molar, PbI₂ 0.25 M) were dissolved in gamma-butyrolactone (GBL). The anti-solvent dichloromethane (DCM) steadily diffused into the vial of the precursor solution containing a piece of silicon substrate. Single crystals were grown on the silicon substrate with the slow diffusion of the DCM vapor.

### Example 2: Protocol for Short-Wave IR Device Fabrication

Cleaning the Fluorine Doped Tin Oxide (FTO) Substrate:

FTO glass was cleaned by ultra-sonication with detergent for 15 minutes, followed by washing with deionized water, acetone, and isopropanol, respectively. The FTO substrate was further treated with an ultraviolet/O₃ cleaner (UVO) for 30 min.

Coating an Electron Transport TiO₂ Layer:

a blocking-TiO₂ layer was prepared as following: a 0.15 M solution of titanium diisopropoxide dis(acetylacetonate) (75 wt % in isopropanol) in 1-butanol was spin-coated on the cleaned FTO substrate at 700 rpm for 8 s, then 1000 rpm for 10 s, and finally 2000 rpm for 40 s. The coated FTO was left to dry at 125° C. for 5 min. A mesoporous TiO₂ layer was spin-coated on the blocking TiO₂ layer with TiO₂ paste diluted in ethanol (2:7 wt %) (Dyesol 18NRT, Dyesol) at 2000 rpm for 20 s, after the substrate cooled down at room temperature. The TiO₂ film was annealed at 550° C. for 1 h and cooled down to room temperature after the substrate dried at 100° C. for 5 min.

Post-Treatment of the TiO₂ Film:

the TiO₂ film was immersed into a 0.05 M aqueous TiCl₄ solution at 90° C. for 15 min, followed by washing with de-ionized water and drying at 500° C. for 30 min.

Coating of Short-Wave IR Film Materials:

a mixed precursor solution was prepared by dissolving PbI₂ and mixed cation iodides of MAI and NH₂NH₃I in DMF. The solution was spin-coated at 3000 rpm for 15 s on the mesoporous TiO₂ coated substrate at 100° C., which was followed by annealing at 120° C. for 30 min. The precursor solution was then kept at 70° C. during the entire process.

Coating of Hole Transport Material (HTM):

an HTM layer was spin-coated on the short-wave IR materials coated substrate with a speed of 3000 rpm for 20 s at room temperature. The HTM solution, composed of Spiro-MeOTAD, was prepared in 1 ml chlorobenzene by mixing Spiro-MeOTAD (72.3 mg), 28.8 μL 4-tert-butylpyridine, and 17.5 μL Li-TFSI [lithium bis(trifluoromethanesulfonyl)imide] solution (concentration: 520 mg of Li-TFSI in 1 mL). The solution was stirred at room temperature for 10 min to yield a clear and light green solution.

Deposition of Back Contact Gold:

a 60 nm gold contact was deposited on top of the HTM layer by thermal evaporation. The deposition of gold layer was made at 1.0 Å per second at one time.

### Example 3: Characterization

UV/Short-Wave IR Measurements:

the UV and short-wave IR absorbance spectra were collected using a spectrophotometer (Varia Cary 5000 UV-Vis-NIR spectrometer) in the range of 300 nm-2500 nm.

X-Ray Diffraction (XRD) Measurements:

XRD data were measured with a Bruker D8 Discover X-ray diffractometer. A typical spectrum was scanned from 10° to 40° with a step size of 0.05° and a scan speed of 1.0° per second.

Scanning Electron Microscope (SEM) Measurements:

a field emission SEM (FEI Quanta 450 FEG) was used to investigate the surface morphology of the films.

Photoluminescence and Lifetime Measurements:

steady-state photoluminescence spectra were taken under excitation by 1.27 mw 633 nm continuous-wave (CW) He—Ne laser and detected with a spectrometer with a CCD detector (TE-cooled, Newton, Andor). The laser incident angle was set at around 30° with respect to the surface normal and the photoluminescence collection angle was set at 60° with respect to the sample. Time-resolved fluorescence lifetime measurements were obtained under excitation by 400 nm pulsed laser (20 ps, 2.5 MHz, PDL 800B PicoQuant) and detected by a time-correlated single photon counting (PicoQuant).

Near IR Photon-Conversion Measurements:

the J-V measurements were carried out by only using the Keithley 2401 Source Meter. A light source (SLS201, Thorlabs, USA) was used to produce 400 nm-1800 nm light source. A ⅛ m monochromator (CM110, Spectral Products, USA) was placed behind the light source to select the wavelength of interest. A lens pair was used to focus the light on samples on a holder. Currents generated from the short-wave IR devices were taken while the voltage was swept from −1.0 V to 1.0 V with a step of 0.02 V with a delay time of 0.1 s.

Solar Efficiency Measurements and EQE Measurements:

the photocurrent was measured under AM1.5G illumination at 100 mWcm⁻² under a Newport solar Simulator. A KG5-Si reference cell traceable to Newport was used to calibrate light intensity. The effective device area was defined as 8.0 mm² by an aperture mask. Average device parameters were obtained from at least 6 devices. EQE measurements were performed using a QE system from PV Measurements Inc.

The results of the experiments are now discussed

To fabricate tunable short-wave IR materials, the compositions of NH₂NH₃I vary in starting materials. FIG. 1 shows Vis-IR absorbance spectra of mixed (MA)ₓ(NH₂NH₃)₁₋ₓPbI₃ thin films made of mixed cation iodides precursor solutions of CH₃NH₃I (MAI) and NH₂NH₃I for five molar fractions of x_{MAI}=87.5%, 50, 40, 25 and 20%. Thin film samples were prepared with various molar fractions of CH₃NH₃I in the mixture of CH₃NH₃I and NH₂NH₃I: x_{MAI}=m_{MAI}/(m_{MAI}+m_{NH}_{₂}_{NH}_{₃}). The fraction compositions stated here are based on the initial concentrations of the precursors, and the actual composition of the crystallized films may be different slightly. The concentration of PbI₂ was fixed at 0.5 M (230 mg/ml) and the molar ratio of organic cation iodides to PbI₂ was 2:1. As shown in FIG. 1, strong and broad absorbance occurs in the short-wave IR range from 800 nm-2500 nm when NH₂NH₃I is added, in addition to a typically high absorbance of halide perovskite in the visible region. The absorbance peaks are located at 1180 nm, 1860 nm, 1778 nm, 1681 nm, and 1600 nm for molar fractions of x_{MAI}=87.5%, 50%, 40%, 25%, and 20%, respectively. The broadband short-wave IR peak seems to shift to a longer wavelength from 87.5% to 50%, whereas it shifts to a shorter wavelength as the molar ratio decreases from 50% to 20%. The absorbance exhibits a maximum peak at 1860 nm at a molar fraction of x_{MAI}=50% as shown in the inset of FIG. 1. As shown in FIG. 1, tunable short-wave IR films are controlled with varied compositions of CH₃NH₃I and NH₂NH₃I.

Temperature can be varied in the fabrication of broadband short-wave IR materials. FIG. 2(A) shows Vis-IR spectra of mixed (MA)ₓ(NH₂NH₃)₁₋ₓPbI₃ thin films with a molar fraction of x_{MAI}=87.5% under different deposition temperatures. A red shift occurs as T_{sub} increases from room temperature to 120° C. No distinct short-wave IR peak was observed at room temperature (RT), whereas the near IR peak at 907 nm was found to appear at 80° C. and a further shift up to 1333 nm appears at 120° C. To understand the effect of temperature upon thin film surface crystallization, X-ray diffraction (XRD) experiments were performed on thin films at different temperatures of substrates (T_{sub}). The XRD pattern in FIG. 2(B) shows that the main 20 peaks of x_{MAI}=87.5% thin films are located at 14.040 (110) and 28.3° (220), respectively. Those peaks are the same as those for pure perovskite MAPbI₃, suggesting that the perovskite structures were not disrupted with the addition of NH₂NH₃I. The hydrazinium cation (NH₂NH₃⁺) has the same molecular size (R=217 pm) as the methylammonium cation (CH₃NH₃+). The hydrazinium cation partially substitutes CH₃NH₃⁺ in the unit cell of 3D structure as the main structure still remains since hydrazinium (NH₂NH₃⁺) cation can fit the space of four adjacent corner-sharing octahedral PbI₆ to produce close-packed 3D structure. FIG. 2(C) displays the optical images of the films for the four different temperatures of substrate. The color of the thin films becomes darker and surface coverage gets better with increasing temperature of substrate.

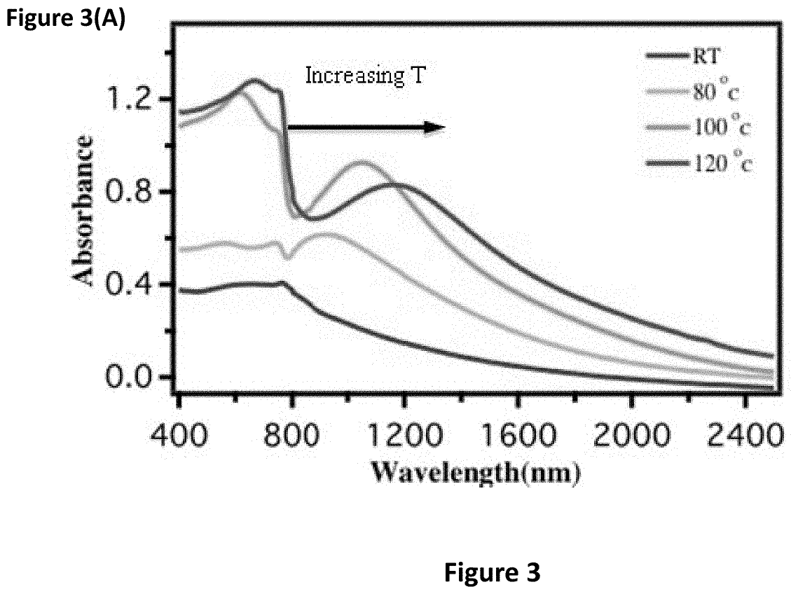

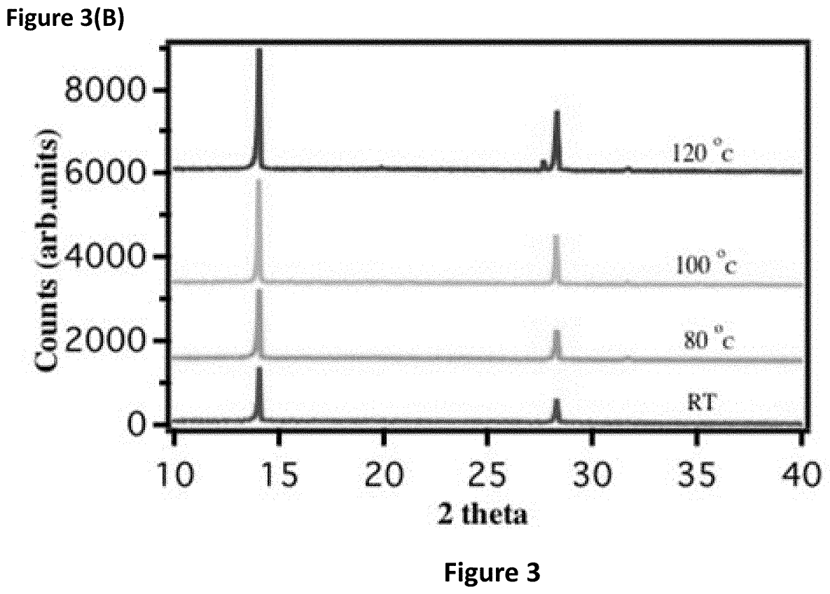

Pure MAPbI₃ thin films were fabricated at different temperatures for comparison purposes. FIG. 3(A) presents Vis-IR absorbance spectra of glass films hot-casted from pure MAPbI₃ (x_{MAI}=100%) at RT, 80° C., 100° C., and 120° C. A red shift occurs as T_{sub} increases from 80° C. to 120° C. There is no distinct short-wave IR peak at room temperature, whereas the near IR peak at 925 nm was found to appear at 80° C. and a further shift up to a short-wave IR peak at 1178 nm appears at 120° C. FIG. 3(B) displays X-ray diffraction pattern of the glass films hot-casted at different temperature for pure MAPbI₃ of x_{MAI}=100%. XRD patterns, located at 14.04° (110) and 28.3° (220), still exist and perovskite structures remain when T_{sub} increases from 80° C. to 140° C. These results indicate that both compositions of pure CH₃NH₃+ and mixed cations (CH₃NH₃⁺ and NH₂NH₃⁺) produce the same tetragonal crystal structure. The red shift of short-wave IR absorbance depends on both the composition of x_{MAI} and T_{sub} for precursor deposition.

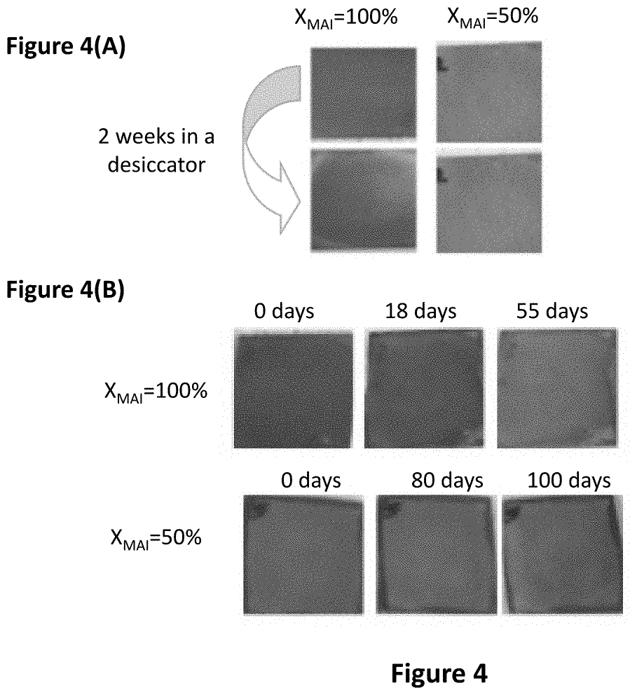

The stability of the short-wave IR materials was investigated by testing the surface morphology of the thin films after storage. FIG. 4(A) shows photographs of the films of (MA)ₓ(NH₂NH₃)₁₋ₓPbI₃ of x_{MAI}=100% and 50% after storage for 2 weeks in a desiccator under vacuum, as compared with those of as-prepared thin films. The short-wave IR films of x_{MA I}=50% remained the black color, while the film of x_{MAI}⁼100% changed the color to yellow. FIG. 4(B) shows photographs of the two glass films of (MA)ₓ(NH₂NH₃)₁₋ₓPbI₃ (x_{MAI}=100% and 50%) with exposure to the ambient condition under the dark for a period of time. The short-wave IR thin film of 50% has good stability after 80 days, while the pure one degraded within only 18 days. It is clearly seen that the short-wave IR thin film of x_{MAI}=50% exhibits much better stability than that of x_{MAI}=100%. A higher fraction of NH₂NH₃⁺ seems to improve the stability of the short-wave IR material. These results suggest that NH₂NH₃⁺ has more coordination with Pb²⁺ than CH₃NH₃⁺, which is due likely to one extra N in NH₂NH₃⁺.

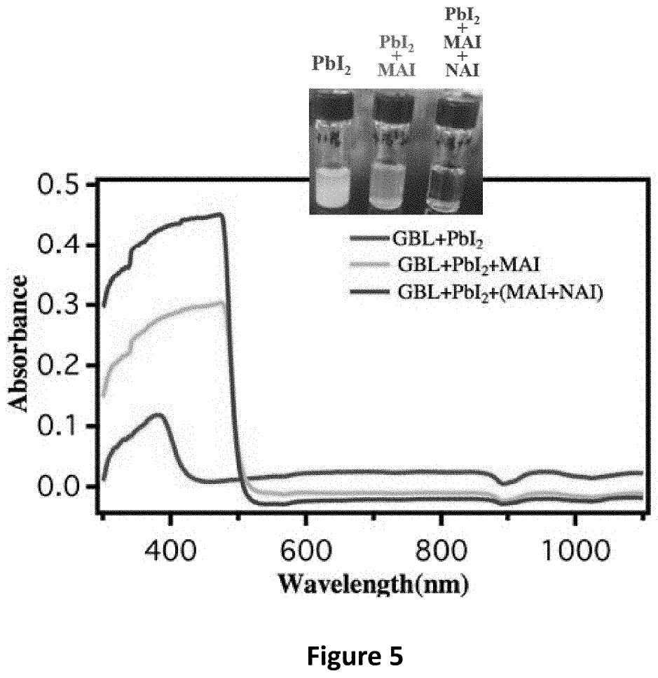

To understand the role of NH₂NH₃I in the formation of the short-wave IR materials, the UV spectra of the original precursor solutions were checked. FIG. 5 shows UV-vis spectra of the three precursor solutions, including PbI₂ alone in γ-butyrolactone (GBL), a mixture of PbI₂ and MAI (CH₃NH₃I) in GBL, and a mixture of PbI₂, MAI, and NH₂NH₃ in GBL. The absorption peak for PbI₂ alone is located at 420 nm, while the addition of MAI and NH₂NH₃I significantly shifts the absorption peak to a longer wavelength of 500 nm. Being a Lewis acid, PbI₂ is known to form adducts with Lewis bases such as oxygen, nitrogen, and sulfur. Nitrogen in hydrazinium and methyl ammonium iodide donate lone pair electrons to Pb²⁺ in PbI₂ to form adducts of mNAI.nPbI₂ and mNH₂NH₃I.nPbI₂, where m/n=1/1 or 1/2. Iodide (I⁻) in the NH₂NH₃I and MAI is a strong donor to PbI₂ to form adduct as well. The background in the UV absorption curve is higher in a mixture of PbI₂ and MAI in GBL than that in a mixture of PbI₂, MAI, and NH₂NH₃I in GBL, which is due to the solubility of PbI₂. Pictured in the inset are the solutions prepared from the three precursors. The presence of MAI and NH₂NH₃I significantly increases the solubility of PbI₂ in the GBL. PbI₂ is not soluble in the GBL even at 70° C., but can be partially dissolved at room temperature after MAI was added into the mixture. The solubility is better when partial MAI was replaced by NH₂NH₃I, which is a further proof that extra nitrogen help adducts formation. These results suggest that NH₂NH₃⁺ with an extra N prefer to form an adduct with PbI₂.

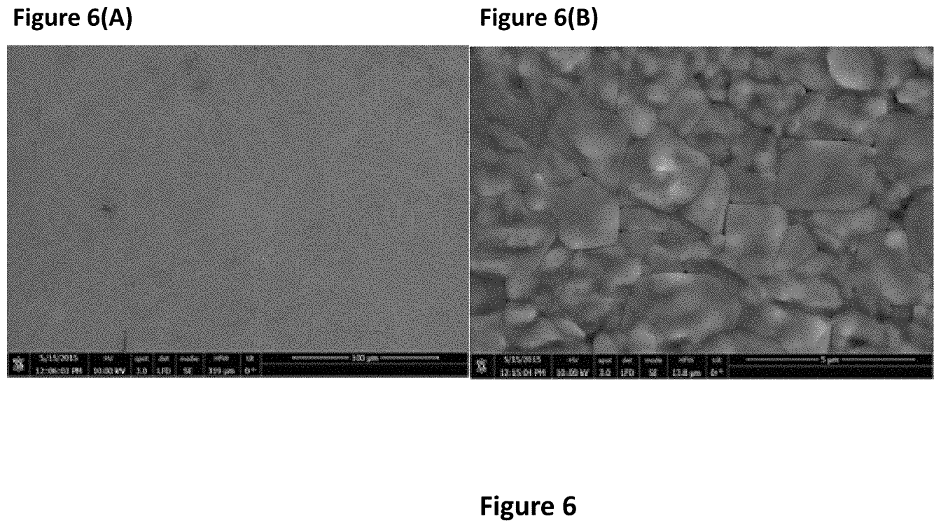

FIG. 6 shows the SEM images of the short-wave IR thin films for x_{MAI}=20%. Uniform and micron size grains are formed at the surface of the thin film. The film displays highly uniform and pinhole free coverage even with a scale of 5 μm.

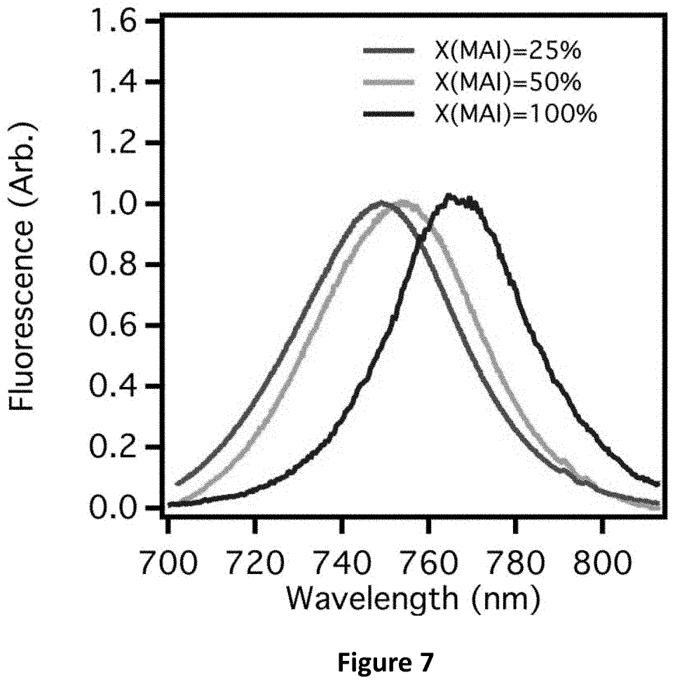

To understand charge transport of the short-wave IR films their photoluminescence and lifetimes were also investigated. FIG. 7 shows photoluminescence spectra of the short-wave IR films with different molar ratios. The maximum peaks are located at 747 nm, 753 nm, and 767 nm, for x_{MAI}=25%, 50%, and 100%, respectively. The photoluminescence spectra shows a slight red shift as CH₃NH₃ in the molar ratio increases.

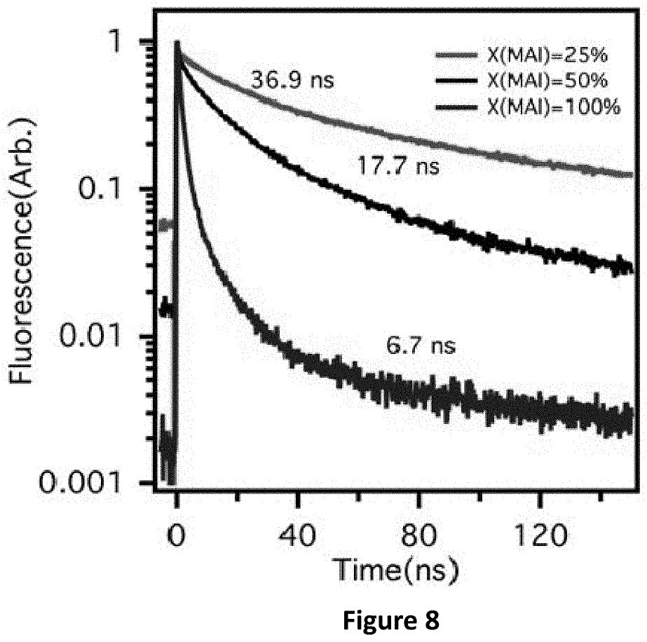

FIG. 8 shows the photoluminescence kinetic traces of the short-wave IR films for x_{MAI}=25%, 50% and 100% under low fluence of ˜10¹⁴ photons/cm³. The lifetimes are 36.9 ns, 17.7 ns, and 6.7 ns for x_{MAI}⁼25%, 50% and 100%, respectively. For a given mobility of the short-wave IR films, the diffusion length of carriers increases as the molar fraction of NH₂NH₃I increases.

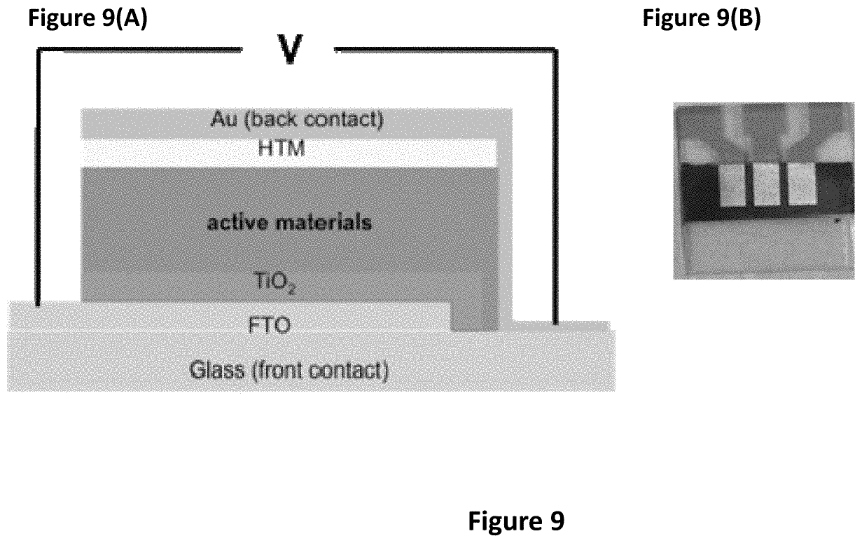

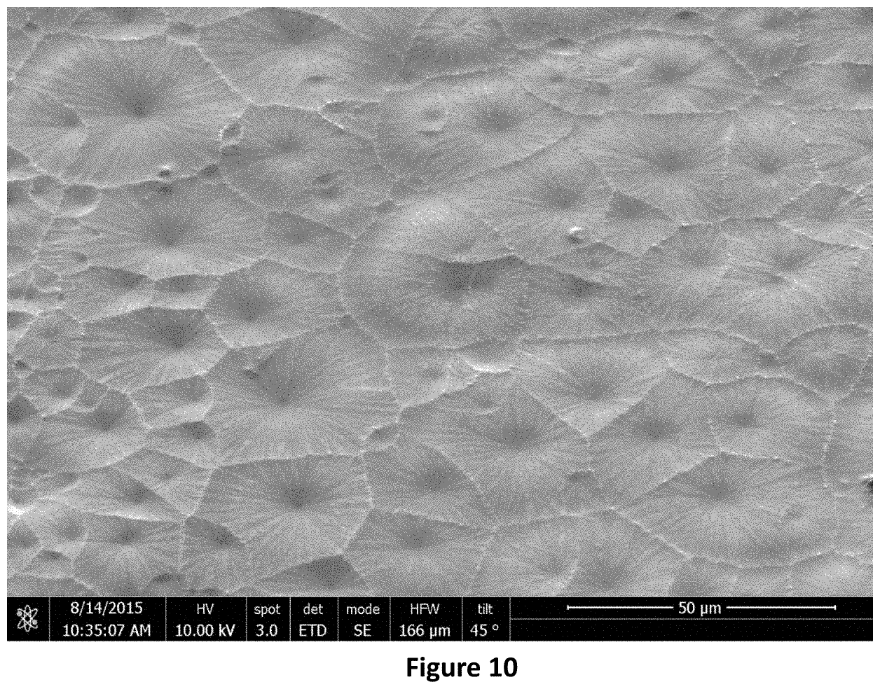

In order to measure current generation of the short-wave IR materials, devices made of the short-wave IR materials as schematically shown in FIG. 9(A) were fabricated. A planar device configuration was used. TiO₂ acts as electron transport layer, while Spiro-MeOTAD acts as a hole transport layer. FTO and gold act as two contacts, respectively. In FIG. 9(B), a photograph of a typical device made of the short-wave IR materials is shown. FIG. 10 shows surface morphology of the short-wave IR devices. Micro-sized grain and full coverage surface is seen, indicating that the surface of short-wave IR devices is well covered.

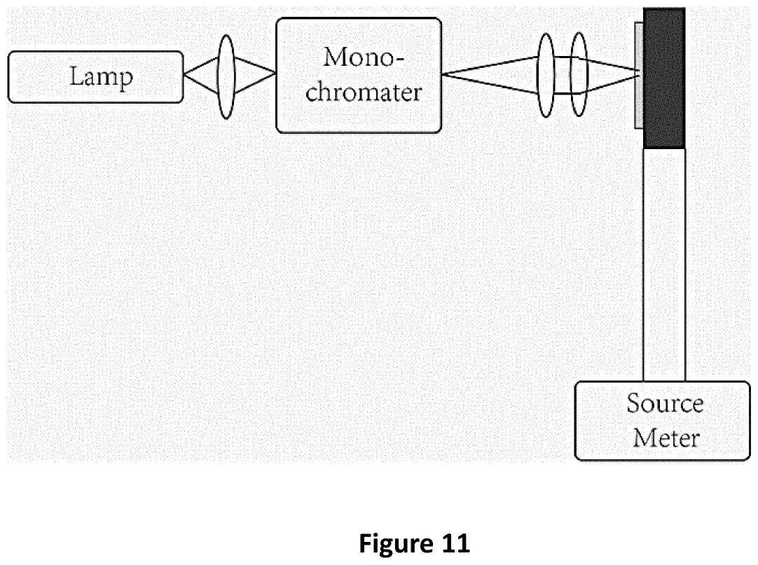

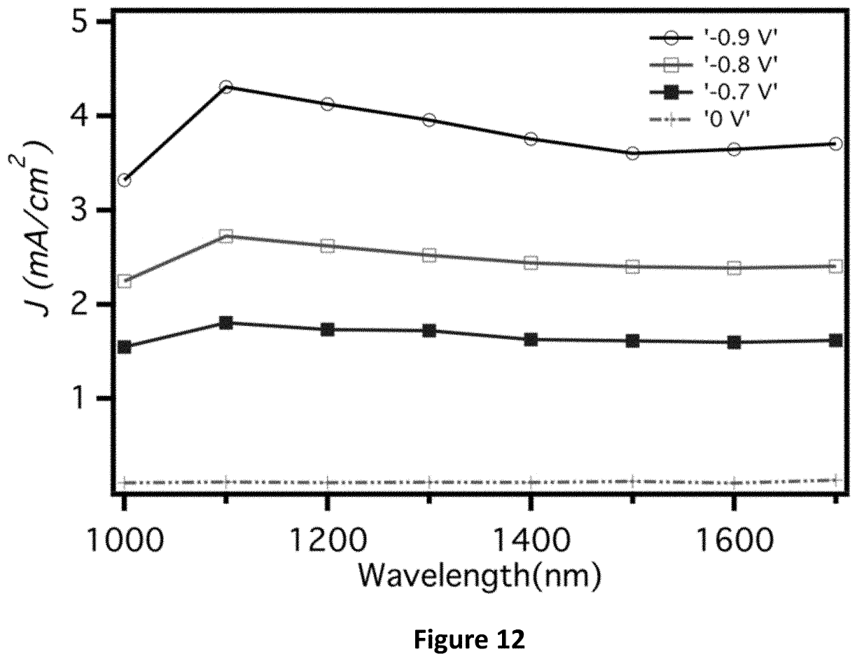

FIG. 11 shows a schematic of the experimental setup for short-wave IR photon-to-current measurements. In this setup, a light source (SLS201, Thorlabs, USA) was used to produce 400-1800 nm light source. A ⅛ m monochromator (CM110, Spectral Products, USA) was placed behind the light source to select wavelength of interest. A lens pair was used to focus the light on the sample on a sample holder. A Keithley 2401 Source Meter was used to apply bias and measure current. The current generated from the short-wave IR devices was taken while the voltage was swept from −1.0 V to 1.0 V with a step of 0.02 V with a delay time of 0.1 s. Current densities generated from a short-wave IR device with the x=87.5% as a function of wavelength are shown in FIG. 12, from 1000 nm to 1700 nm with a step length of 50 nm by rotating a grating in the monochromator, under the four applied voltages, −0.9 V, −0.8 V, −0.7 V, and 0 V. “−” represents that the negative terminal from the source meter is connected with the FTO contact and the positive terminal from the source meter is connected with the gold contact. Under zero and positive biased, no current was generated in this wavelength range. On the other hand, under negative biased, the current was generated and changes as a function of wavelength. The current density is peaked at 1100 nm, which is consistent with the absorption spectra in FIG. 1. With increasing the negative biased, the current increases accordingly.

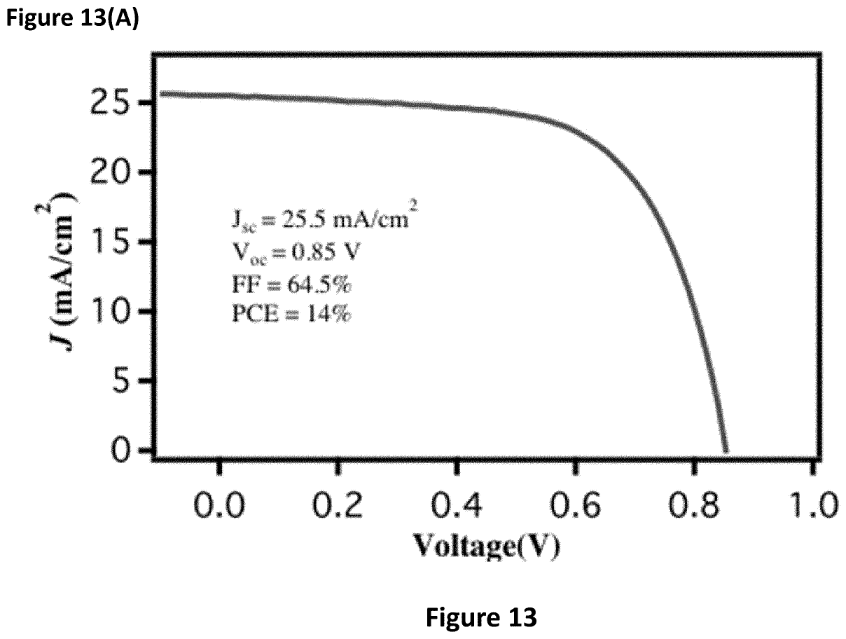

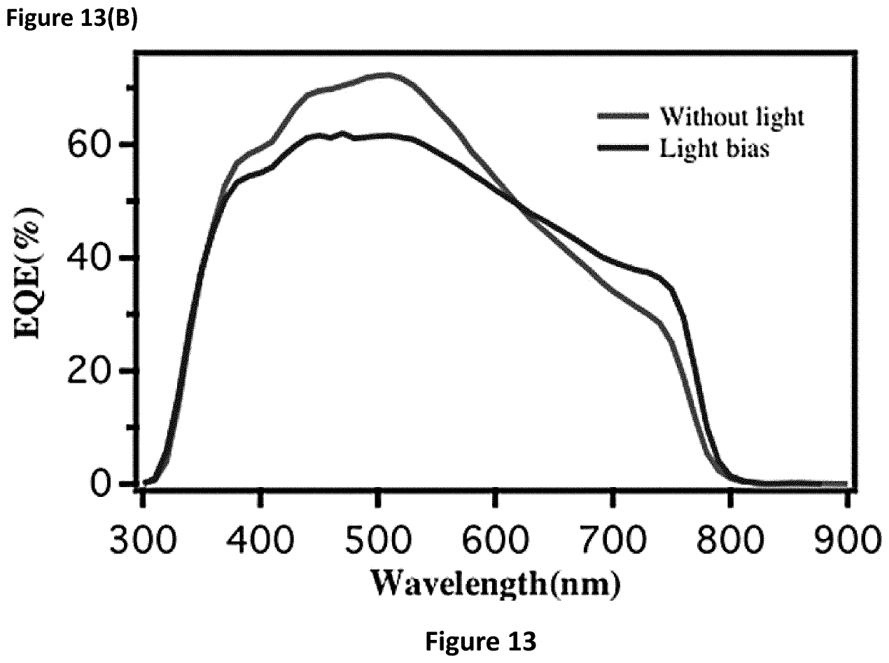

The chemical compositions of mixed (MA)ₓ(NH₂NH₃)₁₋ₓPbI₃ thin films are also used for solar energy conversion. In one example, the ratio of PbI₂ to a mixed of CH₃NH₃I and NH₂NH₃I is kept to be 2:1. FIG. 13 (A) shows a current-voltage curve for the conversion efficiency of a mixed (MA)ₓ(NH₂NH₃)₁₋ₓPbI₃-based solar cell for x_{MAI}=87.5%. The external quantum efficiency (EQE) is also displayed in FIG. 13(B). All the preparation procedures were performed under ambient condition. The power conversion efficiency for the ratio x_{MAI}=87.5% without optimization was found to be around 14%. Further improvement can be easily achieved to optimize the protocol of solar cells fabrication using the materials. One of advantages for our devices is that the materials cover a broad solar radiation from visible light to short-wave IR.

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention. The appended claims are intended to be construed to include all such embodiments and equivalent variations.

1. A composition comprising a mixed salt of empirical formula AₐB_{b}M_{c}X_{d}, wherein:
A is an organic cation;
B is a cation which is different from A;
M is a metallic cation;
X is a halogen anion; and
a, b, c, and d are numbers expressing the relative molar proportions of the cations and anions.

2. The composition of claim 1, wherein B is an inorganic cation.

3. The composition of claim 1, wherein the composition is crystalline.

4. The composition of claim 1, wherein the van der Waals radii of cation A and cation B are in the range of 200-280 pm.

5. The composition of claim 1, wherein A is methylammonium or formamidinium.

6. The composition of claim 1, wherein B is hydrazinium, hydroxylammonium, methylammonium, or formamidinium.

7. The composition of claim 1, wherein M is Pb, Sn, or Ge.

8. The composition of claim 1, wherein X is iodide, bromide, or chloride.

9. The composition of claim 1, wherein the empirical formula of the mixed salt can be represented by the formula (CH₃NH₃)ₓ(NH₂NH₃)₁₋ₓPbI₃, wherein 0≤x≤1.

10. The composition of claim 9, wherein x is 0.875, 0.5, 0.4, 0.25, or 0.2.

11. A thin film comprising the composition of claim 1.

12. The thin film of claim 11, wherein the film has a thickness between 300 and 500 nm.

13. A method of fabricating a film of a composition comprising a mixed salt of empirical formula AₐB_{b}M_{c}X_{d}; wherein A is an organic cation; B is a cation which is different from A; M is a metallic cation; X is a halogen anion; and a, b, c, and d are numbers expressing the relative molar proportions of the cations and anions; the method comprising:
providing a mixture comprising a first organic halide AX, an inorganic halide or second organic halide BX, a metallic halide MX₂, and a solvent;
heating a substrate at a temperature T_{sub}; and
disposing the mixture on the substrate.

14. The method of claim 13, wherein the step of disposing the mixture on the substrate comprises hot-casting the mixture on the substrate.

15. The method of claim 13, wherein the step of disposing the mixture on the substrate comprises spin-coating the substrate on the substrate.

16. The method of claim 13, wherein T_{sub} is between 50° C. and 130° C.

17. A photovoltaic stack comprising a substrate, an electron transport layer, a hole transport layer, and a layer comprising a composition comprising a mixed salt of empirical formula AₐB_{b}M_{c}X_{d}; wherein A is an organic cation; B is a cation which is different from A; M is a metallic cation; X is a halogen anion; and a, b, c, and d are numbers expressing the relative molar proportions of the cations and anions.

18. The photovoltaic stack of claim 17, wherein the electron transport layer comprises TiO₂ and the hole transport layer comprises Spiro-MeOTAD.

19. A photodetector device comprising the photovoltaic stack of claim 17.

20. A solar cell comprising the photovoltaic stack of claim 17.
